(19) United States
(12) Patent Application Publication
(10) Pub. No.: US 2010/0092771 A1
(43) Pub. Date: Apr. 15, 2010

(54) BENDING OF GLASS SHEETS

(75) Inventors: Daniel Decroupet, Jumet (BE); Jose Fernandes, Jumet (BE); Kadosa Hevesi, Jumet (BE)

Correspondence Address: OBLON, SPIVAK, MCCLELLAND MAIER & NEUSTADT, L.L.P., 1940 DUKE STREET, ALEXANDRIA, VA, 22314, US

(73) Assignee: AGC Flat Glass Europe SA, Bruxelles (BE)

(21) Appl. No.: 12/520,713

(22) PCT Filed: Dec. 18, 2007
(86) PCT No.: PCT/EP2007/064141

§ 371 Date: Jun. 22, 2009

(30) Foreign Application Priority Data
Dec. 22, 2006 (EP) 06026746.5

(51) Int. Cl. C23C 14/35; C23C 28/00; B32B 15/04; C03C 17/36; B32B 17/06

(52) U.S. Cl. 428/341; 428/457; 428/471

(57) ABSTRACT

The present invention relates to a glazing comprising an assembly of thin layers having at least one conductive metal layer and dielectric layers, in which at least one dielectric layer located under a metal layer is deposited by a high-power pulsed magnetron sputtering process (HPPMS).

The present invention relates to techniques of depositing thin layers by magnetron-type vacuum sputtering commonly referred to by the term “magnetron sputtering”.

Vacuum deposition techniques and in particular magnetron-assisted techniques are dependent on numerous factors, in particular the type of materials, temperature conditions of the substrate on which deposition is conducted, the type of cathodes used, deposition rate, the configuration of the enclosure in which deposition is conducted etc. The presence of all these parameters means that the properties of the thin layers deposited can have magnitudes that vary greatly for the same type of layer. This is the case in particular for the layer structure. The same product may thus be provided in amorphous or crystalline form or with different crystalline structures or a mixture of structures.

Analysis of the layers deposited by these techniques generally shows differences in properties with ideal materials. These differences result in properties that frequently differ from those that should be present or those desired.

An example of clear difference is to be found in the layer systems applied to glazing units that comprise metal, in particular silver, layers and dielectric layers. These systems are used in particular for their selective reflection properties for infrared rays and result in so-called “low-emissivity” glazing units. The reflection of infrared rays is associated with conductivity, which is closely reliant on the structure of the conductive layer and in particular whether it is deficient or not, but also on the configuration of the interface with adjoining layers and particularly with the underlying layers, on which it rests.

Because of the very low thicknesses of the conductive layer, usually in the order of ten nanometres or so, the irregularities of the contact surface with the support layer have a substantial influence on the configuration of the conductive layer itself and therefore on its properties. For this reason, it is acknowledged that it is desirable to apply the conductive layer to a support that has the most regular surface possible.

If the layer in immediate contact with the conductive layer can modify its qualities, this special feature can extend to layers located lower down in the stack. This is particularly true in the case of a layer in contact with the conductive layer that would have a relatively low thickness and that therefore would not absorb any lack of regularity of these lower layers.

Therefore, an aim of the invention is to propose glazing units comprising layer assemblies that have at least one conductive layer that rests on a support formed by one layer or a system of dielectric layers having a structure that enables better properties to be obtained for the conductive layer that it (they) support.

The invention also proposes to provide layers that have smoother and more uniform interfaces.

Another aim of the invention is to provide silver layers that have an increased conductivity for the same mass of silver deposited per unit area. In application of these qualities, it is an aim of the invention to provide glazing units that have an improved selective reflection for infrared rays and therefore an improved emissivity in so-called low-e glazing without increasing the quantity of silver used per unit area, or conversely for the same emissivity allowing less silver to be used.

According to the invention the set aim is achieved with glazing units comprising an assembly of thin layers having at least one conductive metal layer and dielectric layers, in which at least one dielectric layer located under a metal layer is deposited by a high-power pulsed magnetron sputtering process (HPPMS).

Installations that may be used to conduct this type of deposition have been proposed before, e.g. in U.S. Pat. No. 6,735,099. These allow series of pulses to be produced with very high instantaneous power levels over very short periods of a few microseconds or tens of microseconds. Similar arrangements have also been proposed in U.S. Pat. No. 6,296,742, in particular with the primary aim of improving the use of the material that forms the targets. These devices are proposed to improve the uniformity of the layer deposited or to improve the operation of the installations themselves and in particular that of the ionisation pumps, where applicable. The same type of installation is also described in WO 2005/010228 for specific application to magnetron-type deposition in particular in the aim of preventing the occurrence of faults and especially the formation of arcs.

Publication WO 02/103078 also describes a pulsed technique combining two stages in the operation leading to the deposition of a metal layer: a stage of forming elements released at the cathode corresponding to a current of low intensity and a stage of precipitation of the ionised metal vapours corresponding to a high current.

Installations that allow very high power levels to be applied in very short periods in pulsed systems, as indicated above, have essentially been used in the aim of preventing arc formation while maintaining a sufficiently high deposition rate. In particular, these techniques have been proposed for the formation of layers of dielectric materials from metal cathodes in “reactive” deposition processes, thus preventing the shortcomings caused by the mechanism known as “cathode loss”, which results from the formation of an insulating layer on the cathode.

According to the invention it has been found that the use of pulsed systems with instantaneous power levels much higher than the power levels traditionally used in magnetron sputtering processes allows a substantial improvement in the properties of the layers and in particular those associated directly with the structure of these layers.

The implementation of HPPMS techniques of the invention for the formation of certain layers of these systems corresponds to instantaneous power levels developed at the level of the cathode or cathodes. This power is related to the surface of these cathodes. It is this power that enables the phenomena that cause species coming from the cathode to be created on the cathode to be prevented. Therefore, this power also allows the prevention of arc formation in spite of the high voltages used. Moreover, this power also causes the deposited species to accelerate significantly to allow regular and compact deposits.

According to the invention, the operating conditions of the sputtering installations advantageously lead to instantaneous power levels that are higher than 100 W/cm² of cathode surface exposed to the bombardment. This power is preferably higher than 300 W/cm² and particularly preferred higher than 500 W/cm². In practice, the power is restricted by the available supply installations. However, power levels as high as 1500 W/cm² are already usable in some conditions.

Such high power levels cannot be applied for an extended period without the risk of arc formation. The corresponding pulses are therefore of very short duration. The duration of each pulse is not generally more than 300 μs. This duration preferably does not exceed 100 μs and most frequently is 30 μs at most.

While these pulses are very short, their frequency assures that the process remains sufficiently intense. The frequencies used lie between 1 Hz and 150 Hz, for example, preferably between 50 Hz and 30 kHz.

The pulses are necessarily interrupted by a period, in which the cathode is no longer subjected to voltage. The duration of the pulse compared to the whole is a reduced fraction of each period. The instantaneous intensity of the deposition causes the rate thereof to remain sufficiently high and in the same order of magnitude as that obtained by traditional techniques.

The pulse in the form of voltage applied to the cathode does not instantaneously activate a high intensity. This only develops progressively during the course of the pulse. To accelerate the increase in intensity to also correspond with the transfer of material from the cathode, it is therefore preferable to proceed with a pulse that has the highest value from the outset and maintains this same value for the entire duration of the pulse. The pulse is therefore preferably “rectangular” in form. However, depending on the type of pulse generator used, in particular those using “triac” elements, the pulse, although significant from the outset, is no necessarily at its highest value.

Pulses corresponding to the voltages applied to the cathode depend on numerous factors including geometric factors. In general, the voltages applied are higher than 200 V. They are not usually higher than 10000 V and most frequently do not exceed 2000 V.

The arrangements according to the invention can equally be applied to devices in which the cathodes operate in pairs, and to those in which each cathode is independent. In the systems in which two cathodes are used alternately (“twin” systems), the additional advantage of this bipolar system is to better prevent the accidental formation of arcs.

The arrangements of the invention can also be used with plane cathodes as well as with cylindrical cathodes. In the latter case, the power developed is not directed to the whole surface of the cylinder. An approach corresponding to that of plane cathodes is to direct this power to a surface corresponding to the projection of the cylinder on a plane surface. In other words, the length of the corresponding cathode is that of the generators of the cylinder and its width is equal to the diameter of this cylinder.

The invention can also be used in techniques in which a couple of flat or cylindrical cathodes are used, wherein the targets are of a different type, and which operate simultaneously, techniques referred to as “co-sputtering”, one of which or both being supplied in HPPMS mode.

The abovementioned deposition techniques for the dielectrics forming part of the composition of the systems comprising at least one conductive metal layer can be used for all the dielectric layers arranged between the glass sheet and the conductive layer or only for some of these. Considering their role, it is particularly important to apply them for layers for which it is known that deposition leads to structures that can be highly variable and/or whose configuration can be highly variable, depending on the conditions used. It is also generally advantageous to use theses techniques for all layers that have a thickness that means that the surface quality can be somewhat irregular, depending on the special features presented during growth of these layers.

Numerous dielectric materials can be used in the composition of the systems considered according to the invention. The most widely used systems include one or more layers composed of oxides, nitrides or oxynitrides of elements from the group comprising Sn, Zn, Ti, Zr, Al, Si, Bi, Ni, Cr, Nb and mixtures thereof.

The layers in question may also be of these same elements having a low quantity of other elements added as doping agents.

The targets used for the deposition processes according to the invention can be metal targets or ceramic targets.

If according to the invention one or more dielectric layers underlying the metal conductive layer are deposited by HPPMS, similar techniques can also be advantageously used for the other layers of these systems. This is particularly advantageous if the system comprises several conductive layers separated by dielectric layers. In this case, it is advantageous for the same reasons if the second conductive layer rests on dielectric layers deposited in the conditions described above in the case of systems that only have one conductive layer.

According to the invention, in the case of low-emissivity glazing units comprising a silver layer, the quantity of silver per unit area is usually in the range of between 80 and 160 mg/m². These quantities are chosen to provide a good filtration of infrared rays and also to allow a high light transmission.

Implementation of the invention with quantities of silver of 120 to 135 mg/m² advantageously allows a normal emissivity to be obtained that is not higher than 0.045 and is even lower than 0.040.

Expressed in terms of surface resistance, the implementation of the invention in the case of quantities of silver of 120 to 140 mg/m² advantageously leads to a value that is at most equal to 3.8Ω/□. ▪

In more general terms, the advantage of the implementation of the invention can be expressed by what is referred to as “silver efficiency”. This relates to the product of the quantity of silver expressed in mg/m² by the surface resistance expressed in Ω/□.

According to the invention, the efficiency is advantageously lower than −200 Logₙ Q+1400, preferably lower than −200 Logₙ Q+1380 and particularly preferred lower than −200 Logₙ Q+1360. In this expression Q is the quantity of silver in mg/m².

The quantity of silver is measured by fluorescence X and the surface resistance is measured by induced current using a “Stratometer” type apparatus from Nagy GmbH.

The invention is described in detail below by means of examples with reference to the sets of drawings:

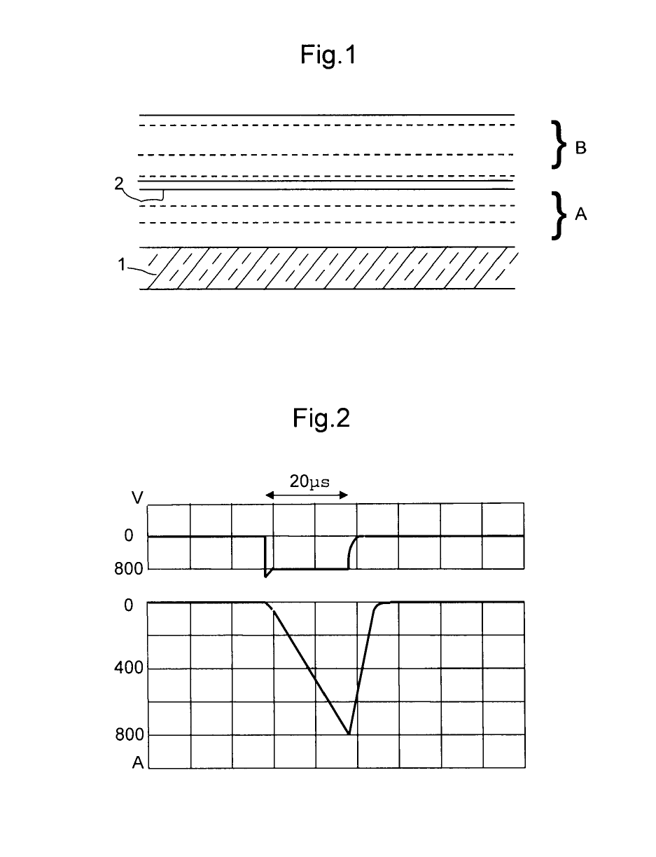

FIG. 1 is a schematic sectional view of a glazing comprising a system of layers of the type aimed at according to the invention;

FIG. 2 shows a type of pulse applied for the technique used according to the invention and the effects on the intensity generated by this pulse;

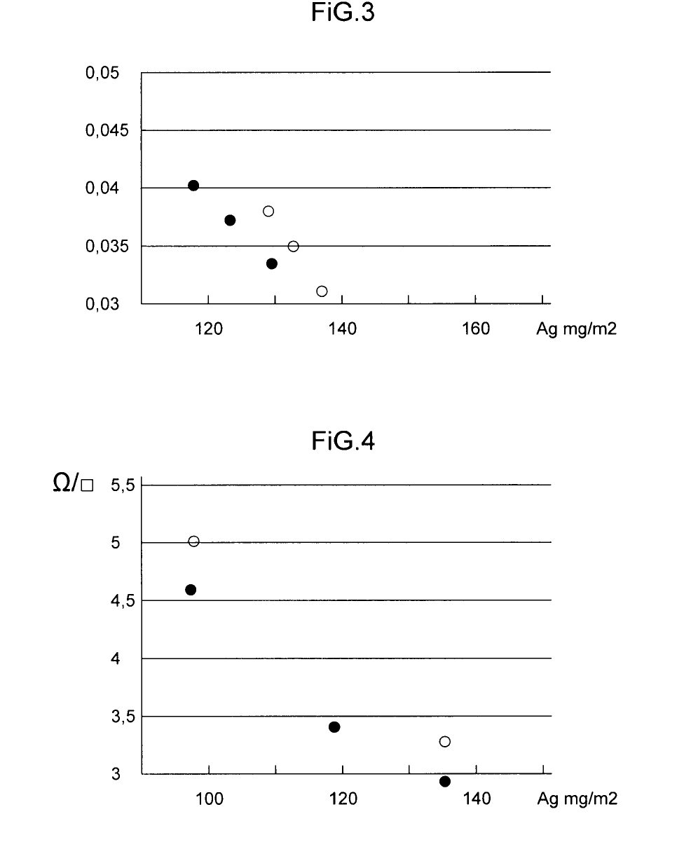

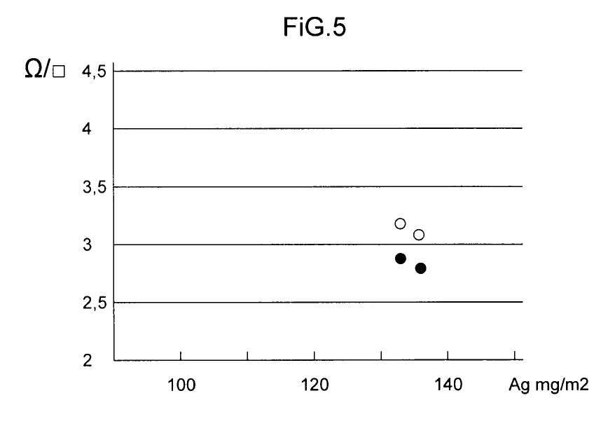

FIGS. 3, 4 and 5 are graphs comparing the qualities of the glazing units coated with layers according to the invention and of other from the prior art.

FIG. 1 is a sectional representation of the elements forming a glazing unit comprising a layer system according to the invention.

A system of thin layers is deposited on the substrate formed by the glass sheet 1 by means of magnetron sputtering. The system necessarily comprises a thin metal layer 2 that selectively reflects infrared, typically a silver or silver-based layer, foreign elements being palladium, aluminium, copper or nickel, for example. This layer is incorporated in an assembly of dielectric layers given the collective reference A for the layers located between the glass sheet 1 and the metal layer 2 and B for the layers located over the metal layer.

Layers A have several functions. For example, the metal layer should be protected from the diffusion of ions, in particular alkaline ions, from the glass. It should also be ensured that the layer system firmly adheres to the glass sheet. This assembly also assists in forming a selective filter by restricting the reflection of visible rays and by leading to as “neutral” a colouration in reflection as possible.

Layers B contribute to the optical properties of the glazing in the same manner. They also have the function of protecting the metal layer from chemical modifications that can result from contact with the atmosphere in contact with the system, in particular oxidation of the metal layer. A so-called “barrier” layer of very low thickness (less than 10 nm in general) is located immediately above the metal layer to protect this during deposition of the upper layers, in particular when these are deposited in a “reactive” manner. The outermost layers also have the role of protecting the assembly from mechanical or chemical modifications.

In the glazing units according to the invention, at least one layer of the assembly A is deposited using an HPPMS technique. Considering the impact it must have on the configuration of the metal layer, this layer can obviously be placed in direct contact with the metal layer. It is understood that the absence of “roughness” at the interface allows optimisation of the conduction of the metal layer for a quantity of metal for a given unit area, or if desired for a given thickness. It appears that the structure of the metal layer and in particular the quality of its surface can equally depend on the lower layers. It is possible to imagine that irregularities in the structure of the underlying layers have an effect on the layers directly in contact with the metal layer, and all the more so when the layer in contact with the metal is thinner. For this reason, the formation of one of the layers or some of these of group A using the HPPMS technique contributes to the features of the glazing units according to the invention.

Where necessary, one or more layers of group B can also be produced by an HPPMS technique. However, the impact on the quality of the metal layer is less immediate than that demonstrated with respect to the layers of assembly A.

The layer system shown in FIG. 1 only has one metal layer. A large majority of low-emissivity glazing systems have a structure of this type. They provide satisfactory insulation properties at an acceptable cost while also retaining a high light transmission as long as the thickness of the metal layer remains relatively low. In order to further increase the insulating property, stacks of layers comprising several metal layers, 2 and sometimes 3, separated by dielectric layers are traditionally used. The invention also applies to such glazing systems. In this case, any one of the dielectric layers underlying any one of the metal layers or several of these same layers are obtained using HPPMS.

FIG. 2 is a simplified representation of a type of pulse applied according to the invention as part of the deposition of one or more dielectric layers using HPPMS methods.

The pulse applied to the cathode, measured in volts, is shown as a function of time in the upper part of the graph. The time scale is in 10 μs per graduation. The line is smoothed to thus eliminate any minimal oscillations observed in relation to the base line in order to simplify understanding thereof.

Starting from an applied voltage of zero, the cathode is abruptly brought to a potential of 800 V. This significant voltage is maintained in the example for 20 μs and returned to o as abruptly as it was applied. The brief but intense pulse is followed by a relatively long off time, during which no voltage is applied.

The measured voltage generated by the pulse indicated above increases rapidly to reach elevated values that lead to an instantaneous developed power per unit area of cathode characteristic of HPPMS techniques. In the case shown, the intensity peak is reached at the instant of the end of the pulse application. It lies at about 800 A.

The end of pulse application leads to a rapid decrease in intensity. The return to the absence of intensity is not immediate. The species ionised during the course of the process continue to be deposited until they disappear.

The frequency of pulses, e.g. some kHz or less, leads to time intervals between two pulses that can be several hundreds or even thousands of times the duration of the pulses. These mechanisms are characteristic of HPPMS techniques.

These differences from the traditional techniques in the conditions set for the deposition device result in specific mechanisms that have not all been fully analysed, but that have certain effects on the properties of the layers such as the behaviour of the targets and control of the process.

In direct regard to the features of the layers, it appears that the observed phenomena come in particular from the energy passed to the particles. This energy appears to be substantially higher, which may explain, at least in part, the changes in structure in particular while avoiding the growth of column structures that are detrimental to obtaining very “smooth” surfaces.

This interpretation is only given as an indication. As stressed, the mechanisms involved are still largely the subject of investigation. Their only advantage is to consider the differences distinguishing HPPMS techniques from traditional techniques, as the following practical examples will show.

The tests were conducted using a “SPIK 2000A-20” pulsing module produced by MELEC.

### EXAMPLE 1

In this example a layer system comprising the following, starting with glass:
a layer of ZnO of 235-270 Å;
a layer of Ag at the rate of 119-270 mg/m²;
a “barrier” layer of Ti of 30 Å;
a layer of ZnO of 235-270 Å,

is deposited onto a 4 mm thick sheet of clear “float” glass.

Deposition is conducted with pulsed DC current (PMS) for all the layers apart from that of ZnO for the tests according to the invention. In the examples according to the invention the ZnO layer in contact with the glass below the silver layer is deposited by HPPMS.

The processes for the deposition of the ZnO layers are reactive in an atmosphere of silver containing oxygen at a pressure of 7 mTorr.

In the traditional method, the pulse frequency is 150 kHz. Taking into consideration the duration of pulses, the instantaneous power reaches a value of 2.7 W/cm² of cathode. The formation of the same ZnO layer by HPPMS is conducted at a frequency of 3 kHz with pulses of 10 μs each. The power peak applied to the cathode then increases to about 355 W/cm². This instantaneous power is more than 100 times that used according to the traditional method.

FIG. 3 indicates the normal emissivity values of the glazing comprising this layer system obtained as a function of the quantity of silver of the conductive layer. On the figure the clear dots correspond to the samples in which the deposits of ZnO were conducted during the traditional technique, the black dots relate to the deposit of the first ZnO layer by HPPMS.

It is clearly determined that in the case of equal quantities of silver, the normal emissivity is lower in the tests according to the invention or, what amounts to the same thing, that a given normal emissivity is obtained while having a less significant silver layer.

The observed indication is still that the improvement is all the more noticeable as the thickness of the silver layer is lower. This confirms the idea that the improvement is at least partly due to a more even ZnO/Ag interface. In fact, it is known that ZnO has a tendency to form column structures, particularly when in a relatively thick layer. The consequence of this is that on such a structure a thin silver layer is subject to the irregularities of such a structure. The thicker the silver layer, the less, relatively, the influence of these irregularities makes itself felt. Thus, the advantage of the glazing according to the invention tends to decrease in the case of thicker silver layers.

The consequence of these results is that it is possible to reduce the quantity of silver in a given system, and this possibly allows an improvement in the light transmission or/and a better control of the colour neutrality. It is also possible to simply obtain a better emissivity.

### EXAMPLE 2

In a second series of tests, the layer system is composed of two separate layers below the silver. A 65 Å layer of ZnOx is still positioned in contact with the silver layer. A 150 Å layer of TiOx is reactively deposited onto the glass. The ZnOx and TiOx deposits result from metal cathodes.

The atmosphere conditions are analogous to those of Example 1.

The HPPMS technique is conducted at a frequency of 0.58 kHz and with pulses applied over 20 μs in accordance with the diagram shown in FIG. 2.

Firstly, only the ZnOx layer is deposited using HPPMS. The maximum instantaneous power reaches the value of 1115 W/cm² of exposed cathode.

For comparison, the ZnOx layer is deposited this time with non-pulsed continuous current. The power directed to the surface of the cathode is 3.6 W/cm², or approximately 400 times less than in the case of HPPMS.

The results are shown in FIG. 4, in which the electrical resistance of the system is measured as a function of the quantity of silver per unit area of the layer.

The resistances and statement of calculated silver efficiency as shown below are as follows respectively for the comparative tests and those according to the invention:

| | | Quantity of Ag mg/m² | | |
|---|---|---|---|---|
| | | 100 | 120 | 135 |
| Comparative | RΩ/□ | 5 | | 3.25 |
| | efficiency | 499 | | 439 |
| According to the | RΩ/□ | 4.58 | 3.45 | 2.97 |
| invention | efficiency | 458 | 414 | 401 |

As above, the clear dots are those corresponding to the comparative examples, while the black dots are those corresponding to the invention.

It is noted that the resistance is substantially lower with an equal quantity of silver in the case of the systems, in which the ZnOx layer is deposited by HPPMS. It is also noted that the difference is all the more significant as the silver layer is less substantial.

Whether the ZnOx layer alone is under the silver, as in Example 1, or whether it rests on a first dielectric layer, the effect of the invention is the same and is explained by the same reasons.

### EXAMPLE 3

This example reproduces Example 2 except that this time the ZnOx layer is obtained by traditional DC deposition, whereas the TiOx layer is produced either by DC or by HPPMS. In other words, it is the layer that is not in contact with the silver that is the subject of comparison.

In the tests the pressure of the argon/oxygen atmosphere for deposition of the titanium oxide is 5 mTorr. The power density is 8 W/cm² in DC mode and 880 W/cm² in HPPMS mode.

As in Example 2, the results are expressed by the resistance as a function of the quantity of silver.

Quantity of Ag mg/m²

| | | 134 | 139 |
|---|---|---|---|
| Comparative | RΩ/□ | 3.2 | 3.1 |
| | efficiency | 429 | 431 |
| According to the | RΩ/□ | 2.9 | 2.8 |
| invention | efficiency | 389 | 389 |

It is also noted that the products obtained according to the invention have a lower resistance with an equal quantity of silver. In other words, the influence on the structure of the silver layer can result not only from the layer immediately in contact with it, but also indirectly. As indicated above, this incidence seems to result from an irregular underlying structure being able to lead to an irregular structure of the layer located over it and in contact with the conductive layer, which results in a change in the properties of the latter.

The use of deposition by HPPMS for the two layers located under the silver layer clearly also results in a better conductivity of this silver layer.

1. A glazing comprising an assembly of thin layers having at least one conductive metal layer and dielectric layers, in which at least one dielectric layer located under a metal layer is deposited by a high-power pulsed magnetron sputtering process (HPPMS).

2. The glazing according to claim 1, in which the at least one metal layer is a layer having silver.

3. The glazing according to claim 1, wherein the at least one dielectric layer deposited with HPPMS exhibits a power density per unit area of cathode of at least 100 W/cm².

4. The glazing according to claim 1, in which the deposits of layers by HPPMS are made at a frequency of 1 Hz to 150 kHz.

5. The glazing according to claim 4, in which each pulse has a duration that is at most equal to 300 μs.

6. The glazing according to claim 5, in which each pulse has a duration that is not more than 30 μs.

7. The glazing according to claim 1, in which the maximum pulse voltage applied is at most equal to 10000V.

8. The glazing according to claim 1, in which in the case of the layers deposited by HPPMS, the pulses applied to the cathode are of unipolar voltage and substantially rectangular in form.

9. The glazing according to claim 1, in which in the case of the layers deposited by HPPMS, two cathodes are coupled and the pulses applied are bipolar and substantially rectangular in form.

10. The glazing according to claim 1, in which a dielectric layer deposited by HPPMS comprises at least one of an oxide, a nitride, and an oxynitride of an element selected from the group consisting of Sn, Zn, Ti, Zr, Al, Si Bi, Ni, Cr, Nb and a mixture thereof.

11. The glazing according to claim 10, in which a dielectric layer deposited by HPPMS is formed from one of the elements of the group in question with a second element in a low amount forming the doping agent of the first.

12. The glazing according to claim 1, in which the layer system comprises a layer in contact with the metal layer formed from a zinc oxide compound deposited by HPPMS.

13. The glazing according to claim 1, in which the layer system comprises at least one layer of a titanium oxide compound and at least one layer of a zinc oxide compound, one of which at least deposited by HPPMS.

14. The glazing according to claim 2, comprising a silver layer corresponding to a quantity of silver per unit area of 80 to 160 mg/m².

15. The glazing according to claim 14, in which the silver layer with a mass per unit area of 120 to 135 mg/m² has a normal emissivity not higher than 0.045.

16. The glazing according to claim 14, in which the surface resistance for a quantity of silver of 120 to 140 mg/m² is at most equal to 3.8Ω/□.

17. The glazing according to claim 2, comprising at least two silver layers separated by dielectric layers, wherein at least one dielectric layer under any one of the silver layers is obtained by HPPMS deposition.

18. The glazing according to claim 14, in which the silver efficiency is lower than −200 Logₙ Q+1400, wherein Q is the quantity of silver expressed in mg/m².

19. The glazing according to claim 1, wherein the at least one dielectric layer deposited with HPPMS exhibits a power density per unit area of cathode of at least 300 W/cm².

20. The glazing according to claim 1, in which the deposits of layers by HPPMS are made at a frequency of 50 Hz to 30 kHz.

21. The glazing according to claim 4, in which each pulse has a duration that is at most equal to 100 μs.

22. The glazing according to claim 1, in which the maximum pulse voltage applied is at most equal to 2000V.

23. The glazing according to claim 2 comprising a silver layer corresponding to a quantity of silver per unit area of 100 to 140 mg/m².

24. The glazing according to claim 14, in which the silver layer with a mass per unit area of 120 to 135 mg/m² has a normal emissivity not higher than 0.040.
